(19) United States
(12) Patent Application Publication
(10) Pub. No.: US 2007/0010089 A1
(43) Pub. Date: Jan. 11, 2007

(54) Method of forming bit line of semiconductor device

(75) Inventors: Jung Ryul Ahn, Namyangju-si (KR); Seok Kiu Lee, Seongnam-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/482,134

(22) Filed: Jul. 5, 2006

(30) Foreign Application Priority Data
Jul. 7, 2005 (KR) 10-2005-61373

(51) Int. Cl. H01L 21/4763

(52) U.S. Cl. 438/629; 257/E21.577

(57) ABSTRACT

A method of forming a semiconductor device includes forming a contact hole in a first interlayer insulating layer that is provided on a semiconductor substrate. The contact hole has a sidewall defined by the first interlayer insulating layer. A first conductive layer is provided within the contact hole. The first conductive layer directly contacts the first interlayer insulating layer that defines the sidewall of the contact hole. The first conductive layer is etched to define a recess within the contact hole, the recess being provided directly above the first conductive layer. An interface metal layer is provided within the recess. A second interlayer insulating layer is formed on the interface metal layer. The second interlayer insulating layer is etched to expose the interface metal layer. A second conductive layer is deposited on the exposed interface metal layer to form a bit line.

### BACKGROUND

The present invention relates to a semiconductor device and more particularly, to a method of forming a conductive structure in a semiconductor device.

As the semiconductor device shrink in size, the RC delay from capacitor coupling between adjacent conductive components are becoming a more serious concern. One such a RC delay relates to the bit line.

A first interlayer insulating film is deposited on a semiconductor substrate on which various structures including the gate and the junction region had formed. A region of the first interlayer insulating film is etched to form a contact hole through which the junction region is exposed. The contact hole is filled with polysilicon to form a contact plug.

A second interlayer insulating film made of boron-doped phosphorus silicate glass (BPSG), for example, is deposited on the first interlayer insulating film in which the contact plug is formed. The second interlayer insulating film is etched to form a contact hole (i.e., a bit line contact) so that the contact plug is exposed. A barrier metal film, e.g., Ti/TiN film, is deposited in the bit-line contact hole and the second interlayer insulating film. The barrier metal film coats the bit-line contact hole. A tungsten film is deposited on the barrier metal film and fills the bit-line contact hole, thus forming a tungsten bit line.

The barrier metal film is used to coat the bit-line contact hole to serve as a diffusion barrier and also facilitate adhesion of the bit-line contact plug to the second interlayer insulating film. However, the barrier metal tends to have a higher resistivity than the bulk metal (e.g., tungsten or aluminum) that is used to fill the contact hole.

As semiconductor devices are miniaturized, the line width of the memory cell becomes smaller as well as other components used in the device including bit lines and bit-line contact holes. In semiconductor devices of 100 nanometers or less, the pattern sizes of the elements (i.e. source, drain, and gate) below the first interlayer insulating film are reduced The space between the patterns of the conductive lines is also decreased. These conductive lines may be bit lines, word lines, metal lines, etc. Accordingly, the RC delay from the coupling capacitance of these conductive lines reduces the device operational speed more noticeably. For example, in the flash memory device, conductive lines that may generate coupling capacitance adjacent to the first bit line may include an underlying word line, neighboring second and third bit lines, an overlaying metal line, and so on. The word line and the first bit line are separated from each other by the first interlayer insulating film, but a first mutual capacitance exists therebetween.

Furthermore, the second and third bit lines adjacent to the first bit line are also electrically separated from each other by the second interlayer insulating film, but a second mutual capacitance exists therebetween. In addition, the first bit line and the overlaying metal line are also electrically separated from each other by the third interlayer insulating film, but a third mutual capacitance exists therebetween.

In these coupling capacitances, the thickness of the bit line pattern and the distance between neighboring bit lines are important factors. In other words, to reduce the bit line gap, it is advantageous if the thickness of the bit line is reduced and the distance between neighboring bit lines is widened. If the thickness of the bit line and the distance between neighboring bit lines decrease, the resistance of the bit lines increases. Accordingly, both factors need to be taken into consideration to obtain the optimal conditions.

### SUMMARY OF THE INVENTION

The present invention provides a manufacturing method for a semiconductor device for decreasing the resistance in a contact plug, via plug or a conductive line (e.g., bit line). An embodiment of the present invention provides a method of forming a bit line of a semiconductor device in which a first conductive layer provided in a contact hole is etched to a predetermined depth; an interface metal layer is formed and bit lines are then formed on the interface metal, whereby the bit line resistance increase and capacitance increase associated with the barrier metal layer can be prevented.

Another embodiment of the present invention provides a method of forming a bit line of a semiconductor device, in which the contact hole and the bit line are formed at the same time, thereby simplifying the process, preventing plasma damage associated with the metal patterning, thereby improving the reliability of cells.

According to an aspect of the present invention, there is provided a method of forming a bit line of a semiconductor device including the steps of; forming a first interlayer insulating film on a semiconductor substrate on which predetermined structures are formed; forming a contact hole; forming a first conductive layer within the contact hole; etching the first conductive layer to a predetermined depth; forming an interface metal layer on the etched first conductive layer and partly within the contact hole; forming a second interlayer insulating film on the entire structure; etching the second interlayer insulating film so that the interface metal layer is exposed; and then depositing a second conductive layer.

According to one embodiment, a semiconductor device, comprising includes a substrate having a gate and a doped region on one side of the gate; a metal plug provided in a contact hole defined by an insulating layer to contact the doped region, the metal plug contacting the insulating layer at a sidewall of the contact hole; and an interface metal layer provided within the contact hole and on the metal plug.

In yet another embodiment, a method of forming a semiconductor device includes forming a hole in a first insulating layer to expose a conductive structure provided below the first insulating layer, the hole having a sidewall defined by the first insulating layer; providing a first conductive layer within the hole at least until the hole is completely filled, the first conductive layer directly contacting the first insulating layer that define the sidewall of the hole; etching the first conductive layer to define a recess within the contact hole, the recess being provided directly above the first conductive layer; providing an interface metal layer within the recess; forming a second insulating layer on the interface metal layer; etching the second interlayer insulating layer to expose the interface metal layer; and depositing a second conductive layer on the exposed interface metal layer. The hole is used to make a contact plug or a via plug.

### BRIEF DESCRIPTION OF THE DRAWINGS

FIGS. 1A to 1E are cross-sectional views illustrating a method of forming a bit line of a semiconductor device according to an embodiment of the present invention.

### DETAILED DESCRIPTION OF EMBODIMENTS

The present invention will be described in detail in connection with certain embodiments with reference to the accompanying drawings.

It is to be understood that the present invention is not limited to only the fabrication of NAND flash memory devices, but may be applied to not only DRAM and SRAM adopting the damascene process, but also other device fabrication technologies implementing fine conductive circuit lines. In the present invention, however, the NAND flash memory device will be described as an example.

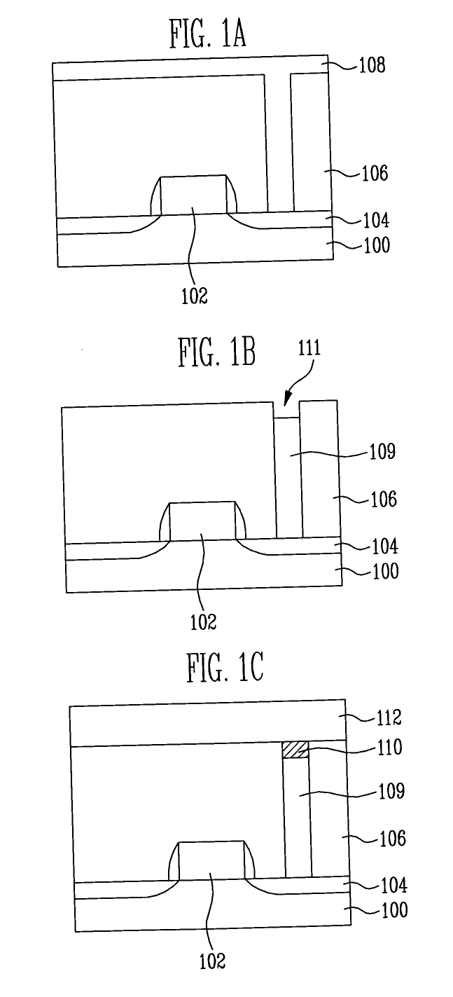

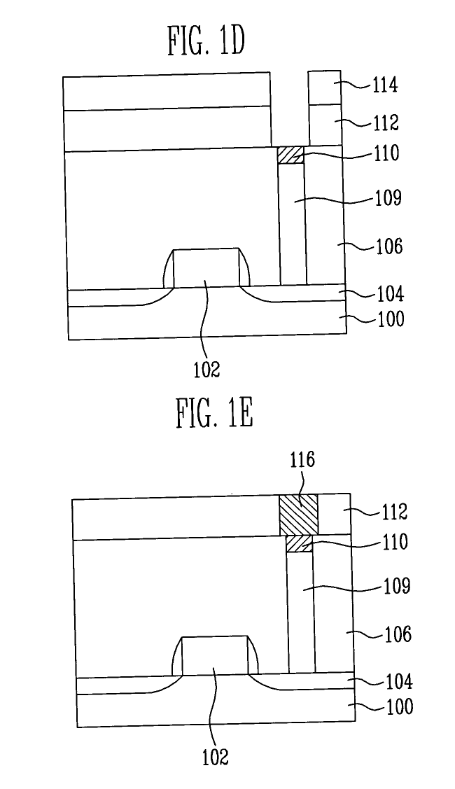

Referring to FIG. 1A, a semiconductor substrate 100 has an isolation structure (not shown) is formed thereon. The isolation structure is formed by a Shallow Trench Isolation (STI) process to define an active region and a field region.

A gate pattern 102 having oxide film spacers formed on both sides of the gate is formed on the semiconductor substrate 100 of the active region. A junction region (a source/drain region) 104 is formed by performing an impurity implant.

A first interlayer insulating film 106 is formed over the gate and isolation structure. A contact hole is formed in the first interlayer insulating film 106 which the junction region 104 is partially exposed. A first conductive layer 108 is provided within the contact hole and directly over the first interlayer insulating film 106 to form a contact plug. The first conductive layer 108 may be formed using any one of tungsten (W), aluminum (Al) and copper (Cu) or combination thereof, but may also be formed using suitable polysilicon.

Since the first conductive layer 108 directly contacts the first interlayer insulating film 106, a barrier metal layer (e.g., TiN) is not provided on the sidewalls of the contact hole. The barrier metal film typically has a higher resistivity than the bulk metal (the first conductive layer 108), so the resistivity of the contact plug can be reduced if more of the bulk metal is used to fill the contact hole.

Referring to FIG. 1B, the first conductive layer 108 is etched by an etch-back process using an etchant having a high, etch selectivity to the first conductive layer 108. A contact plug 109 is formed within the contact hole, such that an upper surface of the contact plug 109 is about 100 to 5000 Å below an upper opening of the contact hole. That is, the etch-back process is performed to define a recess 111 with to a depth of 100 to 5000 Å above the contact plug 109.

Referring to FIG. 1C, an interface metal layer 110 is formed on the entire structure in such a way to completely fill the recess 111 and is then planarized by a chemical mechanical polish process. The interface metal layer 110 may be formed using titanium (Ti) or titanium nitride (TiN). A second interlayer insulating film 112 is formed on the entire structure including the interface metal layer 110.

The interface metal layer 110 is provided between the contact plug 109 and the second interlayer insulating film 112 to prevent a “blow-up” or damage of the second interlayer insulating film 112 during a subsequent anneal step. The interface metal layer 110 is not needed on the sidewall of the contact hole due to the different orientation of the atoms in the vertical direction of the second interlayer insulating film 112.

The processes of FIGS. 1B and 1C are the process sequence when the contact plug of the NMOS and cell drain region is formed. When the bit line contact plug of the PMOS and cell source region is formed, the process sequence is changed. That is, after the contact hole is formed, the interface metal layer 110 is not deposited until the first conductive layer 108 is deposited.

Referring to FIG. 1D, after a photoresist film 114 is formed on the entire structure, the photoresist film 114 is etched to a predetermined pattern. The second interlayer insulating film 112 is etched using the photoresist film 114 as a mask, exposing the interface metal layer 110. As can be seen from the figure, the etch width of the second interlayer insulating film 112 is made to be larger than that of the interface metal layer 110 to include a margin of error for misalignment.

Referring to FIG. 1E, after the photoresist film 114 is stripped, a second conductive layer 116 is formed so that it is brought in contact with the interface metal layer 110. The second conductive layer 116 may be formed using any one of tungsten (W), aluminum (Al) and copper (Cu) or combination thereof.

As described above, according to an embodiment of the present invention, the interface metal layer is formed within the contact hole. The process of the present invention is performed with the existing damascene process. Accordingly, since the contact and the bit line can be formed at the same time, the process can be simplified. In addition, since plasma damages associated dry etch, which is accompanied by metal patterning, can be prevented, the reliability of the cells can be improved.

In addition, according to an embodiment of the present invention, after the first conductive layer buried in the contact hole is etched to form a recess of a predetermined depth, the interface metal layer is formed in the recess and the bit line is formed on the interface metal layer, so that the thickness of the interlayer insulating film between the bit lines in a fine line width is maintained without change. Accordingly, an increase of a bit line resistance value and an increase of a capacitance value, which is incurred by the barrier metal layer, can be prevented.

While the invention has been described with what is considered to be specific embodiments, it is to be understood that the invention is not limited to the disclosed embodiments. For example, the present invention may be applied to form via plugs as well as contact plugs. Various modifications and equivalent arrangements are included within the spirit and scope of the appended claims.

What is claimed is:

1. A method of forming a semiconductor device, comprising:
forming a contact hole in a first interlayer insulating layer that is provided over a semiconductor substrate;
providing a first conductive layer within the contact hole at least until the hole is filled;
etching the first conductive layer to define a recess within the contact hole, the recess being provided directly above the first conductive layer; and
providing an interface metal layer within the recess thereby forming a contact plug.

2. The method as set forth in claim 1, wherein the first conductive layer includes elemental metal.

3. The method as set forth in claim 1, wherein the recess has a depth of 100 to 5000 Å, the first conductive layer provided in the contact hole is a contact plug contacting a doped region of the semiconductor substrate.

4. The method as set forth in claim 1, wherein the interface metal layer includes titanium (Ti) or titanium nitride (TiN).

5. The method as set forth in claim 1, further comprising the step of performing a chemical mechanical polish process after the first conductive layer is provided in the contact hole.

6. The method of claim 1, wherein the first conductive layer is selected from tungsten (W), aluminum (Al) and copper (Cu) or combination thereof.

7. The method of claim 1, further comprising;
forming a second interlayer insulating layer on the interface metal layer;
etching the second interlayer insulating layer to expose the interface metal layer; and
depositing a second conductive layer on the exposed interface metal layer to form a bit line.

8. The method as set forth in claim 7, wherein an etch width of the second interlayer insulating layer is set to be greater than that of the interface metal layer in order to prevent misalignment.

9. The method as set forth in claim 7, wherein the second conductive layer is selected from tungsten (W), aluminum (Al), and copper (Cu) and combination thereof.

10. A method of forming a semiconductor device, comprising:
forming a hole in a first insulating layer to expose a conductive structure provided below the first insulating layer, the hole having a sidewall defined by the first insulating layer;
providing a first conductive layer within the hole at least until the hole is filled;
etching the first conductive layer to define a recess within the contact hole;
providing an interface metal layer within the recess;
forming a second insulating layer on the interface metal layer;
etching the second interlayer insulating layer to expose the interface metal layer; and
depositing a second conductive layer on the exposed interface metal layer.

11. The method of claim 10, wherein the hole is used to form a contact plug and the conductive structure is a doped region defined on a semiconductor substrate.

12. The method of claim 10, wherein the hole is used to form a via plug and the conductive structure is a conductive layer.

13. A semiconductor device, comprising:
a substrate having a gate and a doped region on one side of the gate;
a metal plug provided in a contact hole defined by an insulating layer to contact the doped region, the metal plug contacting the insulating layer at a sidewall of the contact hole; and
an interface metal layer provided within the contact hole and on the metal plug.
